(19) United States
(12) Patent Application Publication
(10) Pub. No.: US 2016/0081200 A1
(43) Pub. Date: Mar. 17, 2016

(54) METHOD FOR MANUFACTURING CIRCUIT BOARD BY ETCHING POLYIMIDE

(71) Applicant: KINSUS INTERCONNECT TECHNOLOGY CORP., Taoyuan (TW)

(72) Inventors: CHEN-LIN WANG, Chiayi County (TW); JIUNN-CHENN LU, Tainan City (TW); CHIH-CHANG SU, Taoyuan County (TW)

(21) Appl. No.: 14/487,233

(22) Filed: Sep. 16, 2014

(51) Int. Cl. H05K 3/44; H05K 3/42

(52) U.S. Cl. CPC H05K 3/44; H05K 3/423

(57) ABSTRACT

A method for manufacturing circuit board includes steps of forming upper and lower copper foil layers on upper and lower surface of a PI substrate, respectively, etching the upper and lower copper foil layers to form first and second electrical circuits, attaching first and second PI coverlays to the upper and lower copper foil layers, respectively, etching the PI substrate through a PI etching process to form at least one opening exposing the lower copper foil layer, and performing a surface treatment to form a solder layer electrically connected to the electrical circuit of the lower copper foil layer for soldering electrical elements in a subsequent process. Therefore, the circuit board with double side circuit and single side assembly is obtained. The present invention do not employ the process of exposure ink, thereby simplifying the whole manufacturing procedure and greatly improving preciseness of the circuit board.

### BACKGROUND OF THE INVENTION

1. Field of the Invention

The present invention generally relates to a method for manufacturing circuit board, and more specifically to a method for manufacturing circuit board by directly etching a polyimide substrate to form openings exposing a copper foil circuit such that the circuit board is provided with the electrical circuit and the openings for placing electrical elements or components.

2. The Prior Arts

Printed circuit boards (PCBs) are one of the most widely used electrical parts, not only for installing kinds of electrical components, but also for improving stability of the whole electrical operation and preventing the electrical components from dropping off or poor contact. However, the traditional PCB is generally formed of the rigid substrate like epoxy resin, on which the electrical components are fixed. Such a PCB fails to meet the requirement of the products which are formed of the bendable or flexible circuit structure, especially the portable electronic devices with extremely limited size such as mobile phone, digital camera or video camera. Therefore, the manufacturers have successfully developed flexible printed circuits (FPCs), which have smaller size and high packed density of circuit, and are excellently flexible and stretchable, thereby being widely applied to various fields.

In general, the manufacturing flow of the FPC comprises:

the step of cutting, in which an auto cutter is employed to cut the plastic substrate like PI (polyimide), PEI (polyetherimide) or PET (Polyethylene terephthalate) into the flexible substrates with an appropriate size;
the step of mechanically drilling, in which the flexible substrate is drilled to form through holes which pass through layers and are configured for fixing and installing various components in the subsequent process;
the step of forming black holes, in which the through holes are deposited by a carbon particle conductive layer;
the step of electroplating copper, in which the conductive copper layer is formed on the surface of the flexible substrate, including the sidewall and the surface of the through hole;
the step of circuit transferring, in which the conductive copper layer is treated by the exposure, developing and etching processes so as to form the predetermined electrical circuit;
the step of attaching, in which the electrical insulation coverlay is tightly attached to the electrical circuit by means of high pressure and temperature so as to provide protection and prevent contamination;
the step of forming bond pad opening, in which the coverlay is treated by the mechanical process to form the openings, the coverlay is then attached to the electrical circuit to form the bond pad opening exposing the electrical circuit, the whole surface is coated by the exposure ink, the exposure ink is processed by exposure and developing so as to form the bond pad openings in the exposure ink exposing the electrical circuit; and
the step of surface treatment, in which the bond pad openings are processed by manufacturing the nickel-gold layer, nickel-palladium layer or the antioxidant layer for soldering or packaging the electrical components, thereby finishing the circuit board.

Refer to FIG. 1, showing the single side circuit board in the prior arts. The single side circuit board 1 is manufactured by means of the traditional technique, and generally comprises the flexible substrate 10, the electrical circuit 20, the coverlay 30, the bond pad opening 40 and the nickel-gold layer 50. Specifically, the electrical circuit 20 is provided on the flexible substrate 10, the coverlay 30 covers the electrical circuit 20 such that the coverlay 30 and the electrical circuit 20 are tightly combined together, the bond pad opening 40 passes through the coverlay 30 or the ink 70 and is provided on the electrical circuit 20 and further covered by the nickel-gold layer 50.

One drawback of the circuit board 1 in the prior arts is that it is needed for the mechanical process to form the opening of the coverlay, but the common manual alignment or the special tooling commonly used fails to improve preciseness. Even if the exposure ink is used to form the opening, not only the whole manufacturing process becomes much complicated, but also the flexibility of the exposure ink is less than the coverlay.

Additionally, refer to FIG. 2, showing the single side circuit board provided with the electrical elements in the prior arts. The single side circuit board 2 is similar to the circuit board 1 in FIG. 1, and also comprises the flexible substrate 10, the electrical circuit 20, the coverlay 30, the bond pad opening 40, the nickel-gold layer 50 and the ink 70. However, to meet the actual requirement of assembling components, the single side circuit board 2 needs to be bent by 180° as shown by the bent region A in FIG. 2, such that the bond pad opening 40 faces down, as shown by the backside component connection region B in FIG. 2.

One shortcoming of the above single side circuit board 2 is that preciseness for installing the electrical components is greatly reduced because the flexible substrate 10 has to be bent by 180° during the assembly, and some of the electrical components are swapped, thereby increasing the manufacturing complication and negatively affecting the yield rate in mass production.

Please refer to FIG. 3, showing the double side circuit board in the prior arts. The double side circuit board 3 generally comprises the flexible substrate 10, the first electrical circuit 21, the second electrical circuit 22, the first coverlay 31, the second coverlay 32, the bond pad opening 40, the nickel-gold layer 50, the plated through hole (PTH) 60 and the ink 70. The first electrical circuit 21 and the second electrical circuit 22 are provided on the upper and lower surfaces of the flexible substrate 10, respectively, and the bond pad opening 40 passes through the first coverlay 31 or the ink 70 and further covered by the nickel-gold layer 50. In particular, the plated through hole 60 passes through the flexible substrate 10 and is connected to the first electrical circuit 21 and the second electrical circuit 22. One drawback of the double side circuit board 3 is that the exposure ink is needed to manufacture the opening, causing the process more complicated and the circuit board less flexibility.

Therefore, it is greatly needed to provide a new method for manufacturing circuit board comprising the step of forming the appropriate opening by directly etching the PI substrate to expose the corresponding copper foil layer for subsequently installing the electrical elements, which is used to completely replace the traditional process using the exposure ink, such that the single or double side FPC is manufactured by not only simplifying the whole manufacturing process but also greatly improving preciseness of the circuit board and saving material cost, thereby overcoming the problems in the prior arts.

### SUMMARY OF THE INVENTION

The primary object of the present invention is to provide a method for manufacturing circuit board by etching polyimide for forming a single side circuit board, comprising;

forming a copper foil layer on a PI (polyimide) substrate through an electroplating process;
etching the copper foil layer to form an electrical circuit;
attaching a PI coverlay to the electrical circuit on the copper foil layer, and tightly combining the PI coverlay and the electrical circuit under high pressure and high temperature;
performing a PI etching process to remove part of the PI substrate so as to form at least one opening exposing of corresponding part of the electrical circuit; and
performing a surface treatment on the opening of the PI substrate to form a solder layer for electrical connection so as to finish the single side flexible circuit board.

The solder layer of the above single side circuit board is configured for electrically connecting at least one electrical element to the electrical circuit through soldering or packaging in the subsequent process. Without the traditional ink process, the manufacturing process is greatly simplified and preciseness of the circuit board is thus improved.

Another object of the present invention is to provide a method for manufacturing circuit board by etching polyimide so as to form another single side circuit board. Specifically, the method comprises the steps of:

forming a copper foil layer on a PI substrate through an electroplating process; etching the copper foil layer to form an electrical circuit;
forming a large opening in the PI coverlay comprising a plastic layer and an insulation film, attaching a PI coverlay to the electrical circuit, and tightly combining the PI coverlay and the electrical circuit through the high pressure and high temperature process;
coating the exposure ink on the large opening of the PI coverlay, and forming at least one first opening on the ink through exposure;
removing part of the PI substrate by PI etching so as to form at least one second opening exposing the corresponding part of the electrical circuit; and
performing the surface treatment on the first opening of the exposure ink and the second opening of the PI substrate so as to form a solder layer electrically connected to the electrical circuit of the copper foil layer, thereby finishing the single side flexible circuit board.

In the above circuit board, the solder layer on the first and second openings are intended for electrically connecting the electrical elements to the electrical circuit through solder or packaging. That is, the electrical elements are configured on the upper or lower parts of the PI substrate to implement the single side circuit board with double side assembly. Thus, it is possible to overcome the traditional problem which results from the fact that the circuit board has to be bent 180° to solder all the electrical elements on one side of the circuit board.

Additionally, a yet object of the present invention is to provide a method for manufacturing circuit board by etching polyimide so as to form a double side circuit board. The method comprises the following steps:

forming the upper and lower copper foil layers on upper and the lower surface of the PI substrate, respectively;
etching the upper and lower copper foil layers to form the first and second electrical circuits, respectively;
forming the large opening in the first PI coverlay, attaching the first PI coverlay to the first electrical circuit, at the same time attaching a second PI coverlay to the second electrical circuit, and performing a high pressure and temperature process to tightly combining the first PI coverlay and the first electrical circuit as well as the second PI coverlay and the second electrical circuit;
performing the PI etching process on the large opening of the first PI coverlay to remove corresponding part of the PI substrate so as to form at least one opening exposing corresponding part of the second electrical circuit; and
performing the surface treatment on the at least one opening above the second electrical circuit to form the solder layer electrically connected to the second electrical circuit. Thus, the double side flexible circuit board is finished.

The solder layer of the above double side circuit board can be implemented on one side or two sides for electrically connecting the electrical elements to the corresponding electrical circuit of the copper foil layer by soldering or packaging. Therefore, the present invention provides the double side circuit board with double side circuit and single side or double side assembly.

Since the traditional exposure ink is not used, the method of the present invention provides the simpler manufacturing process, thereby greatly improving preciseness of the circuit board.

### BRIEF DESCRIPTION OF THE DRAWINGS

The present invention can be understood in more detail by reading the subsequent detailed description in conjunction with the examples and references made to the accompanying drawings, wherein:

FIG. 1 is a view showing the single side circuit board in the prior arts;

FIG. 2 is a view showing the single side circuit board provided with the electrical elements in the prior arts;

FIG. 3 is a view showing the double side circuit board in the prior arts;

FIG. 4 is a flowchart showing the method for manufacturing the circuit board by etching polyimide according to the first embodiment of the present invention;

FIG. 5 is a view showing the circuit board manufactured by the method according to the first embodiment of the present invention;

FIG. 6 is a flowchart showing the method for manufacturing the circuit board by etching polyimide according to the second embodiment of the present invention;

FIG. 7 is a view showing the circuit board manufactured by the method according to the second embodiment of the present invention;

FIG. 8 is a flowchart showing the method for manufacturing the circuit board by etching polyimide according to the third embodiment of the present invention; and

FIG. 9 is a view showing the circuit board manufactured by the method according to the third embodiment of the present invention.

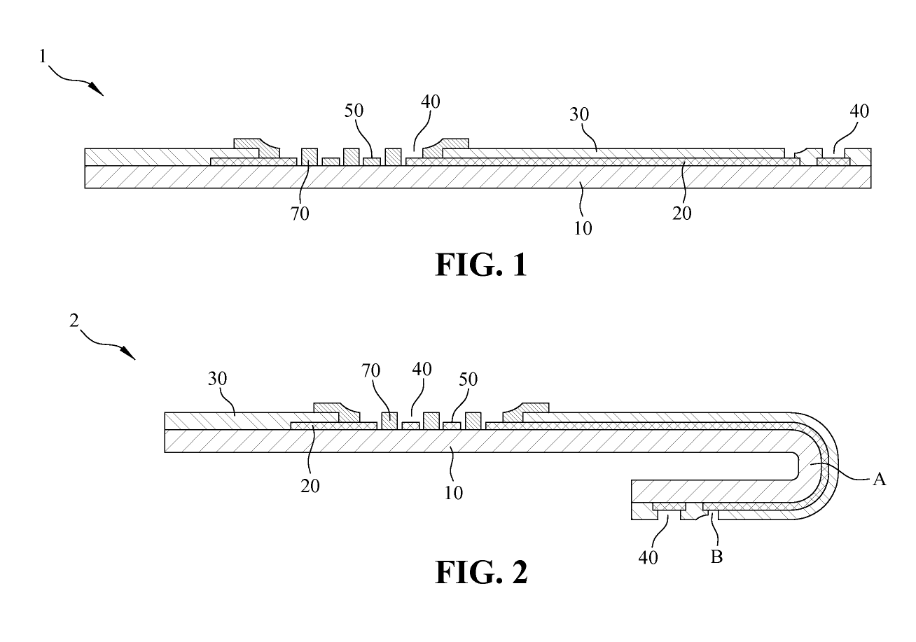

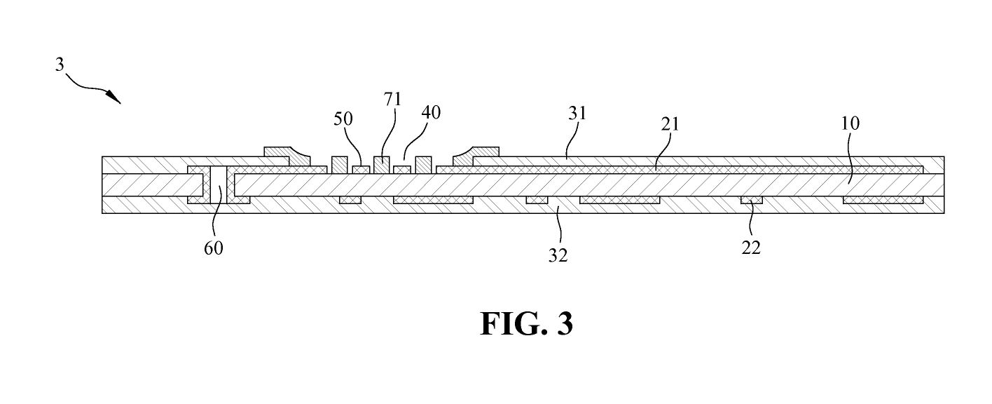

### DETAILED DESCRIPTION OF THE PREFERRED EMBODIMENT

The present invention may be embodied in various forms and the details of the preferred embodiments of the present invention will be described in the subsequent content.

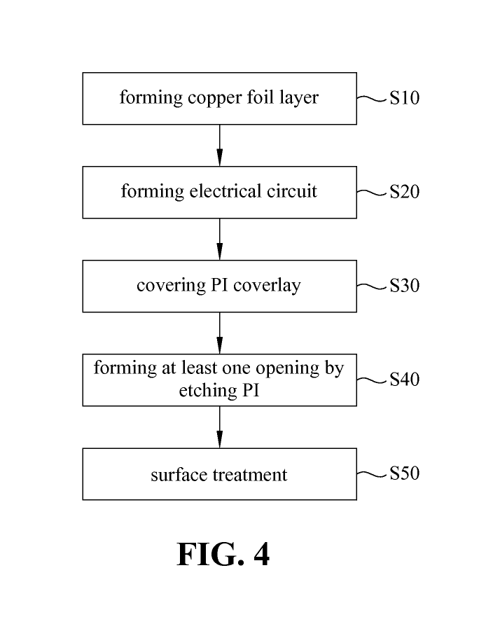

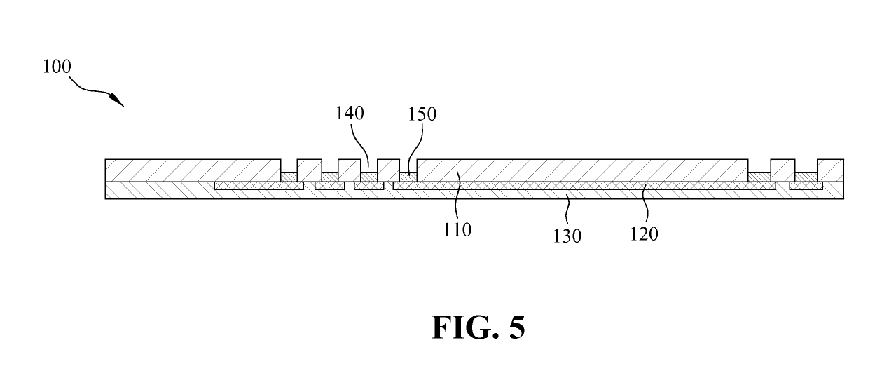

Please refer to FIGS. 4 and 5. Specifically, FIG. 4 illustrates the flowchart of the method for manufacturing the circuit board by etching polyimide according to the first embodiment of the present invention, and FIG. 5 shows the circuit board manufactured by the method of the first embodiment. As shown in FIG. 4, the method for manufacturing the circuit board by etching polyimide of the first embodiment comprises the sequential processing steps S10, S20, S30, S40 and S50 for manufacturing the circuit board 100. First, the method begins at the step S10. With reference to FIG. 5, the process of electroplating copper or the calendaring/rolling process is performed to form the lower copper foil layer on one surface (facing down in FIG. 5) of the PI (polyimide) substrate 110. The lower copper foil layer formed in the step S10 is then etched to form the electrical circuit 120 in the step S20.

Next, the PI coverlay 130 formed of an adhesive layer and an insulation film is attached to the electrical circuit 120, and the high pressure and temperature process is performed to tightly combine the PI coverlay 130 and the electrical circuit 120 in the step S30. The adhesive layer may comprise acrylic or epoxy resin. In the step S40, part of the PI substrate 110 is etched by means of optical aligning so as to form at least one opening 140, which exposes corresponding part of the electrical circuit 120.

Finally, the surface treatment is performed in the step S50 to form the solder layer 150 in the opening 140 of the PI substrate 110 electrically connected to the electrical circuit 120. The circuit board 100 is manufactured. Preferably, the solder layer 150 is formed of the nickel-gold layer, the nickel-palladium layer or the antioxidant layer for soldering the electrical elements or components.

The aspect of the first embodiment according the present invention is that the PI coverlay 130 integrally remains and is used for the PI etching process to etch the PI substrate 110 so as to form the opening. Particularly, the PI etching process is implemented by means of optically aligning, thereby greatly increasing preciseness of the circuit board 100. Furthermore, the traditional exposure ink process is completely omitted such that the whole manufacturing process is simplified and the yield rate is improved.

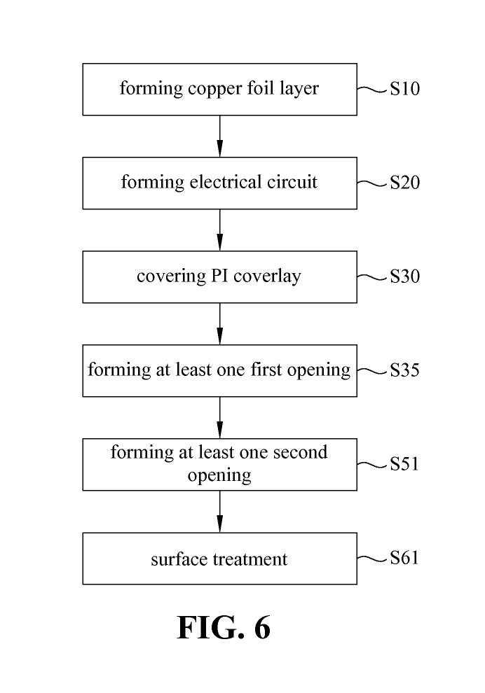

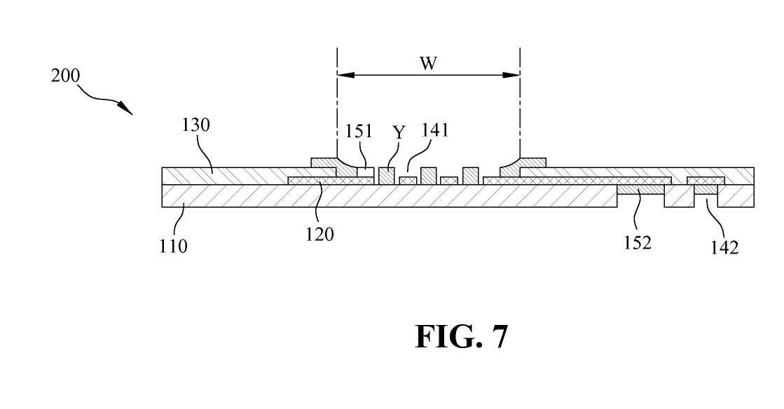

Further refer to FIGS. 6 and 7, illustrating the flowchart and the circuit board according to the second embodiment of the present invention, respectively. As shown in FIG. 6, the method for manufacturing the circuit board by etching polyimide of the second embodiment comprises the sequential processing steps S10, S20, S30, S35, S51 and S61 for manufacturing the circuit board 200. It should be noted that the second embodiment is similar to the first embodiment and only the steps S35, S51 and S61 of the second embodiment are different from the steps S40, S50 and S60 of the first embodiment.

Specifically, the steps S10, S20, S30 of the second embodiment are the same as those of the first embodiment, and thus omitted hereinafter. As shown in FIG. 7, in the step S35, a mechanical process is performed on the PI coverlay 130 to form at least one large opening W, the exposure ink Y is then coated on the PI coverlay 130 and the at least one large opening W, and the exposure ink Y on at least one large opening W is processed by exposure to remove part of the exposure ink Y so as to form at least one first opening 141. The step S51 is performed by removing part of the PI substrate 110 through the PI etching process so as to form at least one second opening 142, which exposes the corresponding part of the electrical circuit 120. Thus, the first opening 141 and the second opening 142 are configured on the two opposite surfaces of the electrical circuit 120, respectively.

Finally, the surface treatment is performed on the first opening 141 and the second opening 142 of the PI substrate 110 in the step S61 such that the first solder layer 151 and the second solder layer 152 electrically connected to the electrical circuit 120 are formed on the first opening 141 of the PI coverlay 130 and the second opening 142 of the PI substrate 110, respectively, thereby finishing the circuit board 200. It is preferred that the first solder layer 151 and the second solder layer 152 are formed of the nickel-gold layer, the nickel-palladium layer or the antioxidant layer.

The primary aspect of the above circuit board 200 is that the first solder layer 151 and the second solder layer 152 are configured for electrically connecting the electrical elements or components to the electrical circuit 120 by soldering or packaging. In other words, the electrical elements or components can be placed on the lower or upper surfaces of the PI substrate to implement the function of double side assembly for the circuit board 200 so as to overcome the problem in the prior arts which results from the fact that the circuit board has to be bent 180° to solder all the electrical elements or components on one side of the circuit board.

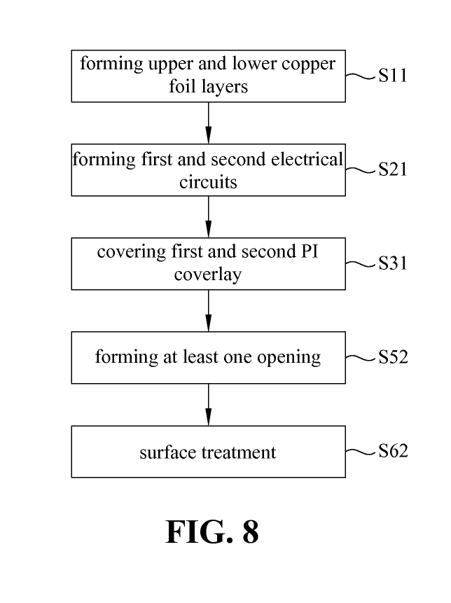

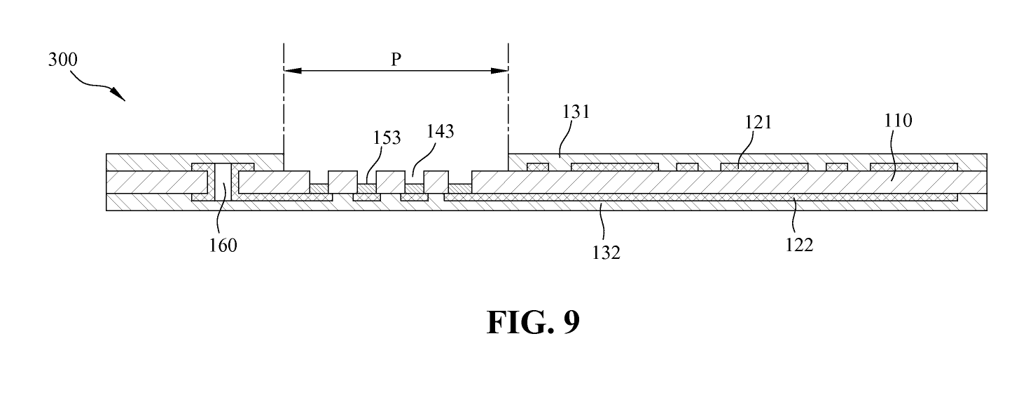

Further refer to FIGS. 8 and 9, illustrating the flowchart and the circuit board according to the third embodiment of the present invention, respectively. As shown in FIG. 8, the method of the third embodiment comprises the sequential processing steps S11, S21, S31, S52 and S62 for manufacturing the circuit board 300.

As shown in FIG. 9, the method of the third embodiment begins at the step S11. The upper and lower copper foil layers are formed on the upper and lower surfaces of the PI substrate 110, respectively. In the step S21, the upper and lower copper foil layers are treated by the copper etching process to form the first electrical circuit 121 and the second electrical circuit 122, respectively. The step S31 is subsequently performed by forming the large opening P in the first PI coverlay 131, attaching the first PI coverlay 131 to the first electrical circuit 121, at the same time, attaching the second PI coverlay 132 to the second electrical circuit 122, and tightly combining the first PI coverlay 131 and the first electrical circuit 121 as well as the second PI coverlay 132 and the second electrical circuit 122 by the high pressure and temperature process.

For the PI substrate 110, the etching process is performed on the large opening P of the first PI coverlay 131 above the first electrical circuit 121 in the step S52 so as to remove the corresponding part of the PI substrate 110 such that the at least one opening 143 is formed and the corresponding part of the second electrical circuit 122 is exposed.

Finally, the opening 143 is processed by the surface treatment to form the solder layer 153 on the opening 143 in the step S62, wherein the solder layer 153 is electrically connected to the second electrical circuit 122, thereby finishing the circuit board 300. The solder layer 153 is preferably implemented by the nickel-gold layer, the nickel-palladium layer or the antioxidant layer.

From the above-mentioned, one aspect of the above circuit board 300 is that the solder layer is provided on one side or two sides configured for fixing the electrical elements or components by soldering or packaging in the subsequent application such that the electrical elements or components are electrically connected to the first electrical circuit 121 and the second electrical circuit 122. The present invention thus provides the circuit board having the double side circuit and the function of the single side or double side assembly. Since the traditional exposure ink is not used, the whole manufacturing process is simplified, thereby greatly increasing preciseness of the circuit board.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for manufacturing circuit board by etching polyimide for forming a single side circuit board, comprising steps of:
forming a copper foil layer on a PI (polyimide) substrate through an electroplating process;
etching the copper foil layer to form an electrical circuit;
attaching a PI coverlay to the electrical circuit on the copper foil layer, and tightly combining the PI coverlay and the electrical circuit under high pressure and high temperature;
performing a PI etching process to remove part of the PI substrate so as to form at least one opening exposing of corresponding part of the electrical circuit; and
performing a surface treatment on the PI substrate to form a solder layer on the at least one opening, wherein the solder layer is electrically connected to the electrical circuit of the copper foil layer for electrically connecting at least one electrical element to the electrical circuit.

2. The method as claimed in claim 1, wherein the PI substrate comprises an adhesive layer and an insulation film, and the solder layer is a nickel layer, a nickel palladium layer or an antioxidant layer.

3. A method for manufacturing circuit board by etching polyimide for forming a single side circuit board, comprising steps of:
forming a copper foil layer on a PI substrate through an electroplating process;
etching the copper foil layer to form an electrical circuit;
attaching a PI coverlay to the electrical circuit on the copper foil layer, and tightly combining the PI coverlay and the electrical circuit under high pressure and high temperature;
performing a mechanical process on the PI substrate to form at least one large opening, coating an exposure to cover the at least one large opening of the PI substrate, performing an exposure treatment on the exposure ink, and removing the exposure ink to form at least one first opening;
removing part of the PI substrate through a PI etching process to form at least one second opening exposing corresponding part of the electrical circuit; and
forming a solder layer on the at least one first opening and the at least one second opening of the PI substrate so as to finish the single side circuit board,
wherein the solder layer is electrically connected to the electrical circuit of the copper foil layer, and the solder layer is configured on different sides of the electrical circuit for electrically connecting at least one electrical element to the electrical circuit.

4. The method as claimed in claim 3, wherein the PI substrate comprises a plastic layer and an insulation film, and the solder layer is a nickel layer, a nickel palladium layer or an antioxidant layer.

5. A method for manufacturing circuit board by etching polyimide for forming a double side circuit board, comprising steps of:
forming upper and lower copper foil layers on upper and lower surface of a PI substrate, respectively;
etching the upper and lower copper foil layers to form first and second electrical circuits, respectively;
forming a large opening in a first PI coverlay, attaching the first PI coverlay to the first electrical circuit, at the same attaching a second PI coverlay to the second electrical circuit, and performing a high pressure and temperature process to tightly combining the first PI coverlay and the first electrical circuit as well as the second PI coverlay and the second electrical circuit;
performing a PI etching process on the large opening of the first PI coverlay to remove corresponding part of the PI substrate so as to form at least one opening exposing corresponding part of the second electrical circuit; and
performing a surface treatment on the at least one opening above the second electrical circuit to form a solder layer electrically connected to the second electrical circuit so as to finish the double side circuit board, wherein the solder layer is configured for soldering at least one electrical element such that the at least one electrical element is electrically connected to the corresponding electrical circuit of the lower copper foil layer.

6. The method as claimed in claim 5, wherein the PI substrate comprises a plastic layer and an insulation film, and the solder layer is a nickel layer, a nickel palladium layer or an antioxidant layer.
